(19) United States
(12) Patent Application Publication
(10) Pub. No.: US 2022/0359258 A1
(43) Pub. Date: Nov. 10, 2022

(54) Method of Manufacturing and Passivating a Die

(71) Applicant: TDK Electronics AG, Munich (DE)

(72) Inventors: Mehrdad Shayganpoor, Graz (AT); Guenter Aflenzer, Premstätten (AT)

(21) Appl. No.: 17/638,053

(22) PCT Filed: Jan. 14, 2021
(86) PCT No.: PCT/EP2021/050721

§ 371 Date: Feb. 24, 2022

(30) Foreign Application Priority Data
Jan. 28, 2020 (DE) 10 2020 102 003.1

(51) Int. Cl. H01L 21/683; H01L 21/78; B81C 1/00

(52) U.S. Cl. CPC H01L 21/6836; H01L 21/78; B81C 1/00896; H01L 2221/68327; H01L 2221/68381

(57) ABSTRACT

In an embodiment, a method for manufacturing and passivating a die includes providing the die having an active frontside including a protrusion, the protrusion configured for electrically contacting the die, covering a portion of the protrusion by a passivation tape before applying a passivation layer, applying the passivation layer on all sides of the die including the frontside and its protrusion in one single process, except on the portion covered by the passivation tape and detaching the passivation tape from the covered portion of the protrusion after applying the passivation layer to expose the portion of the protrusion which forms an electrical contact area.

This patent application is a national phase filing under section 371 of PCT/EP2021/050721, filed Jan. 14, 2021, which claims the priority of German patent application 102020102003.1, filed Jan. 28, 2020, each of which is incorporated herein by reference in its entirety.

### TECHNICAL FIELD

The present invention relates to a method of manufacturing and passivating a die, comprising an active frontside with an electrically conductive protrusion.

### BACKGROUND

A commonly used method for sealing a die comprises a molding process with several steps requiring pre- and post-treatment to apply one or more protective layers to a semiconductor die.

Further state of the art methods for manufacturing and passivating semiconductors are usually based on a wafer level packaging method and comprise multiple steps. Semiconductor wafers are manufactured, comprising two or more different passivation layers applied on several sides of the wafer in several steps. Usually, the passivation layers are deposited by chemical vapor deposition (CVD). Afterwards the wafer is singulated into dies. Examples of such methods are disclosed in US 2014/0091482 A1 or US 2008/0318396 A1.

United States Patent Application Publication No. 2005/0167799 A1 describes a manufacturing method comprising applying a passivation layer on the backside of a semiconductor wafer, laminating the backside with an adhesive tape and dicing of the wafer. Afterwards, as a pre-treatment step, the adhesive tape is expanded to enlarge the gap between the single semiconductor dies, followed by applying a passivation layer on the frontside and the lateral sides of the semiconductor dies.

All of these methods comprise multiple technical extensive steps comprising several passivation steps and pre-treatment and post-treatment steps to passivate the dies and are therefore time-consuming and cost-intensive.

### SUMMARY

Embodiments provide an improved and less expensive and time-consuming method for manufacturing and passivating dies.

The method comprises the following steps:
providing a die comprising an active frontside having a protrusion, which is arranged for electrically contacting the die;
covering a portion of the protrusion by a cover member; and
applying a passivation layer on all sides of the die including the frontside and its protrusion in one single process step, except on that portion covered by the cover member.
Detaching the cover member from the covered portion of the protrusion after applying the passivation layer to expose the portion of the protrusion. No passivation layer covers this portion which is thus defined as an electrical contact area.

The steps are preferably completed in the disclosed order.

By applying the passivation layer on all sides in one single process step, several time-consuming passivation steps can be avoided.

The protruded area may be a solder bump or a thick film metallization.

The cover member may be a passivation tape.

In one method, the cover member may be a passivation tape comprising a first base layer having a first adhesive layer thereon.

The method may comprise the following steps:
providing the die comprising the active frontside having the protrusion;
covering a portion of the protrusion by the passivation tape;
applying the passivation layer on all sides of the die in one single process step, except on that portion covered by the passivation tape; and
delaminating the passivation tape from the covered portion to expose the portion of the protrusion. This portion is not covered by the passivation layer. Therefore this portion is defined as electrical contact area.

The steps are preferably completed in the disclosed order.

After delaminating the passivation tape no post-treatment steps are necessary. In particular, no chemical post-treatment steps like etching are necessary to remove the passivation layer from the electrical contact area as it would be necessary in a commonly used method. By avoiding this step costs and time can be saved.

The die may comprise a semiconductor material. The semiconductor material may comprise a silicon (Si) material. The die based on a semiconductor material can be used for a micro-electro-mechanical system (MEMS) device for different applications. Alternatively, the die may consist of a mineral material. The mineral material may comprise a ceramic. The die can be used as capacitor, varistor or thermistor.

It is possible that the passivation layer is applied by atomic layer deposition (ALD). In general, passivation layers on semiconductor dies and other dies are usually applied by CVD. In principle, in CVD processes, reactive species react in a gas phase under a controlled atmosphere and elevated temperature to deposit a layer. The CVD process is usually performed at relatively high temperature which may potentially introduce impurities from the gas atmosphere into the layer of deposited material. Technically, such a high required deposition temperature for CVD processes limits the choice and hence the functionality of materials including the tape that are involved in the process.

The ALD process, on the other hand, has the main advantage of being capable of depositing layers in a low temperature regime with high uniformity and quality. In general, ALD as a variant of the CVD process, involves the deposition of a monolayer on any target substrate. Multiple monolayers can be deposited by systematically repeating cycles including dosage of gaseous precursor into a deposition chamber, reacting same with the surface of the target and flushing the chamber with an inert gas to purge out the not chemisorbed precursors. In the present method, the ALD process is preferred considering the introduced tape and the specific required passivation material due to the demanded crucial properties of the passivation layer (electrical, mechanical etc.).

Further embodiments provide a method performed at wafer level and hence provides a wafer level packaging method. In said method dies may be manufactured from a wafer by conducting the following steps:

a) providing a wafer, comprising an active frontside with several protrusions, which are arranged for electrically contacting the die, and a backside. On the active frontside a plurality of device structures for a plurality of single devices may be provided;

b) singulating the wafer into single dies. Each die then comprises device structures that realize a single electrical device. Each die further comprises at least one protrusion made from an electrically conductive material;

c) covering a portion of each protrusion by a cover member. It is significant for this method, that the cover member at least partially covers at least one protrusion on each die;

d) applying a passivation layer on all sides, including the frontside, backside and all lateral sides, of the singulated dies in one step, except on the portions covered by the cover member which form electrical contact areas; and

e) detaching the cover member from the covered portions of the protrusions after applying the passivation layer to expose the portions of the protrusions. No passivation layer covers these portions which are thus defined as electrical contact areas.

The steps are preferably completed in the disclosed order.

The cover member includes a passivation tape.

In a method, the cover member includes a passivation tape comprising a first base layer having a first adhesive layer thereon. The passivation tape is laminated on the portions of each protrusion.

In a preferred method, singulating the wafer in step b) comprises the following steps:

i) partial-cut dicing the wafer into dies, each with at least one protrusion, from the frontside;

ii) laminating a grinding tape comprising a second base layer having a second adhesive layer thereon to the frontside of the wafer. After that step the tape covers the frontside of the dies completely;

iii) singulating the dies by grinding the wafer from the backside. In this step, the continuous wafer layer at the backside of the wafer that remains after the partial-cut dicing step is completely removed;

iv) detaching the grinding tape from the singulated dies.

The introduced lower case letters and roman numbers show an obvious sequence of the several steps of the disclosed process. They can be regarded as reference signs, designating a specified procedure.

Since the dicing step is executed before grinding, the risk of backside chipping and die damaging is minimized in the present method. Therefore, this method allows the processing of thinner dies in comparison with dicing after grinding methods.

The wafer may comprise a semiconductor material like silicon or a mineral material like a ceramic. The single dies singulated from the wafer can be used like the single die described above. Thus the wafer level packaging method enables a simultaneous manufacturing of several micro-electronic devices at the same time.

Because of the advantages described above it is preferable to apply the passivation layer by an ALD process. As a further advantage of the ALD process the layer thickness can be easily controlled even if the passivation layer is deposited in a trench or hole having a high aspect ratio such as e.g. at a dicing street. Hence, also the aspect ratio of the dicing street that is the ratio of dicing depth over width of dicing street can be well defined by the ALD process.

In one embodiment, the surface topography of the frontside and the shape of the protrusions thereon is considered for the selection of the grinding tape.

For example, the second adhesive layer on the grinding tape may be thicker than the first adhesive layer on the passivation tape. This allows adhesion of the grinding tape to the whole surface of the frontside independent of a surface topography and the shape of the protrusions thereon. The thick adhesive layer may cover all structures and shapes that are projecting over the frontside surface.

By using an ALD process, it is possible to keep the distance between two adjacent dies during applying the passivation layer in step d) equal to the width of a dicing street produced during dicing in step i). No further step is taken or required to increase the distance between the dies after singulating the dies and before applying the passivation layer. In conventional processes, the individual dies are mounted onto an appropriate tape. This tape is expanded to increase their mutual distances to a minimum required value. In the disclosed embodiment this additional step can be omitted, saving time and costs.

It is possible to apply a protective layer on the frontside of the wafer before dicing in step i). Said protective layer passivates the frontside of the layer. Furthermore, it allows an exact definition of electrical contact points on the frontside by etching openings for vias in said protection layer to expose a desired area for the contact points. The electrically conductive protrusions are positioned on these contact points. They may be formed by soldering metal on the contact points.

In one method, the backside may be covered with a dicing tape, comprising a third base layer having a third adhesive layer thereon, during partial-cut dicing the wafer into dies from the frontside in order to mechanically protect the backside against possible damages like wafer cracks and the like.

The designations first, second and third base layer and adhesive layer do not refer to the order in which the layers are used during the described process. The designation is for distinction only. The layers are components of different tapes, may comprise different materials and may have different properties.

In one method, one or more of the passivation, the grinding and the dicing tape may be detached by a physical method comprising at least one of UV-exposure, if the adhesive is UV-releasable, or heating, if the adhesive is thermally releasable. Such a physical method weakens the adhesive forces of the tapes and thus makes the releasing step easier.

It is possible that a solder bump for electrical interconnection is applied on the frontside of the wafer before laminating or adhering the passivation tape to the frontside. In this case said protrusion is the solder bump.

Alternatively, a thick film metallization for electrical interconnection may be applied on the frontside of the wafer. In this case said protrusion is the thick film metallization.

The solder bump or the thick film metallization may only partially be covered by the passivation tape in step c). Thus, the passivation layer will be partially applied onto non-covered and still exposed areas of the protrusion, e.g. the bump or the metallization, during step d). The size of an electric contact area can be defined by the size of the surface of the protrusion which is covered by the passivation tape. Hence, this size can be defined exactly.

Embodiments further comprises a die as it can be manufactured by the method described above. The die has a passivation layer covering all sides and edges of the die except an electrical contact area. Furthermore, the passivation layer is uniform, continuous and homogeneous on every side. In one embodiment it also has the same thickness on every side. These properties simplify further processing steps on the die.

In an embodiment, the die may be a semiconductor. The semiconductor may comprise a silicon (Si) or silicon carbide (SiC) material. The semiconductor can be used for a micro-electro-mechanical system (MEMS) device. Alternatively, the die may consist of a mineral material. The mineral material may comprise a ceramic. The electric device of the die may be embodied as capacitor, varistor or thermistor.

In an embodiment, a solder bump is applied as a protrusion on a frontside of the wafer for electrical interconnection. The solder bump is partially covered by the passivation layer. Alternatively, a thick film metallization is applied on the frontside for electrical interconnection, which can also be partially covered by the passivation layer. The non-covered portion of the protrusion serves as the electrical contact area for interconnection e.g. with an external circuit environment like a PCB or the like.

The frontside of the die may have two layers. A protective layer seals the frontside. By recesses in this protective layer the electrical contact points can be defined. Herein the word ‘point’ does not have its mathematical meaning. Rather it describes a small defined area.

A passivation layer all around the die is laminated onto the protective layer. The materials of the two layers may be different from each other. The passivation layer protects the die against potential environmental impacts including moisture, chemical contamination or physical damage in subsequent assembly steps.

In one embodiment the passivation layer may be electrically insulating. A passivation layer deposited by ALD may comprise any metal nitride or oxide. In particular the passivation layer may comprise one or more of Al₂O₃, AlN and TiO₂. Al₂O₃ has high electric resistance and high thermal conductivity.

### BRIEF DESCRIPTION OF THE DRAWINGS

In the following, the invention will be explained in more detail with reference to accompanied drawings. The drawings show:

FIG. 1: The frontside of a wafer with an active surface and the backside of the wafer with a passive surface;

FIG. 2A: a cross-sectional view of a single die with a solder bump for electrical interconnection, before applying a passivation layer;

FIG. 2B: a cross-sectional view of a single die with a thick film metallization for electrical interconnection, before applying a passivation layer;

FIG. 3: a top view onto the wafer attached to a dicing tape held by a frame at the backside, after partial-cut dicing;

FIG. 4: a cross-sectional view of the wafer attached to the dicing tape with the backside, after partial-cut dicing;

FIG. 5: a cross-sectional view of the wafer attached to a grinding tape with the frontside, before backside grinding;

FIG. 6: a cross-sectional view of the single dies of the wafer attached to a grinding tape with the frontside, after backside grinding;

FIG. 7: a cross-sectional view of the single dies attached to a passivation tape with the upper surface of the thick film metallization, before applying the passivation layer;

FIG. 8: a cross-sectional view of the single dies attached to a passivation tape with the upper surface of the thick film metallization, after applying the passivation layer;

FIG. 9A: a cross-sectional view of a single die with a solder bump for electrical interconnection, after applying the passivation layer; and

FIG. 9B: a cross-sectional view of a single die with a thick film metallization for electrical interconnection after applying the passivation layer.

Similar or apparently identical elements in the figures are marked with the same reference signs. The figures and the proportions in the figures are not scalable.

### DETAILED DESCRIPTION OF ILLUSTRATIVE EMBODIMENTS

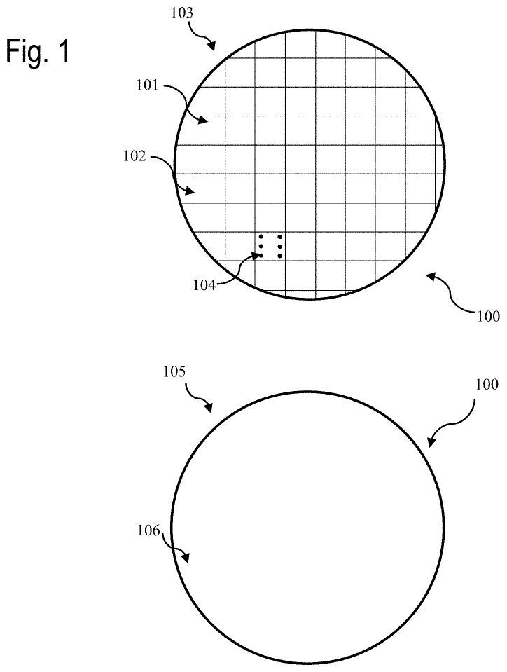

FIG. 1 shows an embodiment of a wafer 100 which is a semiconductor consisting of Si and has a circular shape which can have any size. The semiconductor wafer 100 comprises an array of semiconductor dies 101. The die borders 102 are indicated by virtual lines. Circuit layers or other electric device structures are applied on the frontside 103 of the wafer or are integrated within the die near the frontside. Thus the frontside 103 is designated as active surface.

Bond pads 104 are formed on the active surface connected to device structures. Said bond pads serve as electrical contact points between the wafer and any connected circuitry. Protrusions for electrical interconnections are applied on said bond pads.

The backside 105 of the wafer shown at the bottom part of the figure is free of circuitry. Thus the backside of the wafer may be designated as passive surface. The passive surface 106 may comprise the material of the wafer.

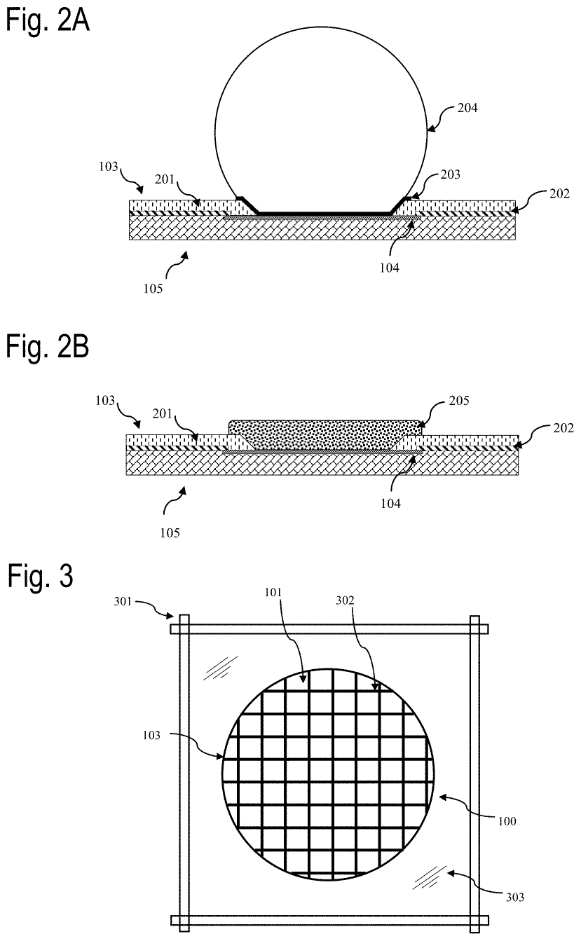

FIGS. 2a and 2b show sectional views of one single die 101 of the wafer 100. On the semiconductor substrate a protective layer 201 and an interlayer 202 are applied. The protective layer 201 may consist of SiO₂ or Si₃N₄. The protective layer 201 may be deposited by a conventional method like sputtering or CVD. The dielectric protective layer 201 defines the size and position of the electrical contact point between the semiconductor and an applied protrusion on the frontside of the wafer (e.g. solder bump, thick film metallization), which is electrically conductive. For that process an etching process is used in the present embodiment to form an opening exposing at its bottom a bond pad 104 through the protective layer 201. Into the opening an under-bump metallization (UBM) 203 is applied. Thereon a conductive solder bump 204 is formed. The solder bump 204 may be deposited by screen printing, ball bumping or a jetting process.

Alternatively, the opening may be filled with a thick film metallization 205 deposited by a conventional sputtering and subsequent electroplating process. Both the solder bump 204 and the thick film metallization 205 enable electrical interconnection between the semiconductor die 101 and the electrical device realized by device structures in or on the die and an external circuitry like a printed circuit board (PCB).

In step a) of an exemplary method a semiconductor wafer as shown in FIG. 1 is provided. A frame 301 is used for holding a tape 303 as shown in figure 3. The tape 303 is formed of a material such as polyethylene or a similarly resilient material. Adhesion of the tape 303 may be supported by applying pressure, vacuum and/or heat. The adhesive layer of the tape 303 may comprise an UV releasable adhesive or any other adhesive that allows a later release of the tape 303. Hence, the tape 303 adheres to the backside 105 of the wafer 100 without forming a permanent bond.

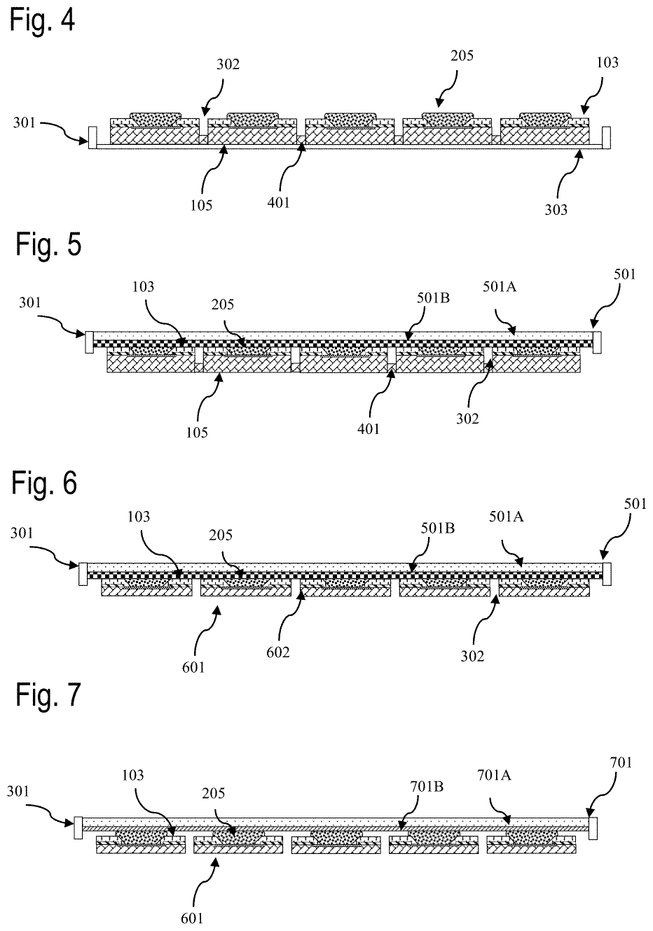

When the tape 303 is attached to the backside 105 of the wafer 100, the wafer 100 is diced into single dies Dolby sawing dicing streets 302 from the frontside 103. The single dies 101 are only partially divided by the dicing step i), as shown in figure 4. The dicing streets 302 are only partial-cut. On the backside 105 of the wafer a continuous layer 401 of wafer material remains.

In a third step ii) illustrated in figure 5 a grinding tape 501 is laminated on the frontside of the wafer 100. The grinding tape 501 may also be held by a frame 301. The tape 501 consists of a base layer 501A and an adhesive layer 501B. The thickness of the adhesive layer 501B depends on the thickness of the solder bump 204, thick film metallization 205 or any other protrusion for electrical interconnection. The layer should be executed in such a way that the adhesive layer 501B covers the whole frontside 103 of the wafer 100 comprising the protective layer 201, the protrusions and the later electrical contact areas.

Next, the adhesive layer of the tape 303 on the backside 105 is detached from the wafer 100. The releasing can be executed by mechanical pressure, heating, UV exposure or a different method depending on the adhesive's properties.

In step iii) the wafer 100 is divided into singulated dies 101 by grinding since the continuous layer on the backside 401 is ground until it is completely removed as shown in FIG. 6. Thus, the ground backside 601 and lateral sides 602 that have already been exposed by the dicing streets 302 of the dies 101 are completely exposed and accessible from the back side and thus are ready for applying the passivation.

The described dicing before grinding (DBG) process allows better control of the dicing process, minimum backside chipping and minimum risk of die damage. The grinding tape 501 protects the active surface on the frontside 103 from damage during backside-grinding.

Once the wafer 100 is ground and the dies 101 are singulated, a specific delamination and lamination process is required to delaminate the grinding tape 501 (step iv) and to laminate a passivation tape 701 (step c) on the frontside 103 of the dies 101, as shown in figure 7. The releasing of the grinding tape 501 can be executed by heating, UV exposure or a different method depending on the adhesive's properties. The passivation tape 701 may be held by a frame 301 and consists of a base layer 701A and an adhesive layer 701B. This passivation tape 701 covers only the later electrical contact areas which shall not be passivated in the following steps. Therefore the adhesive layer 701B of the passivation tape 701 is thinner than the adhesive layer 501B of the grinding tape 501. As an example, the thickness of the adhesive layer 701B of the passivation tape 701 is about 8 μm to 10 μm compared to 20 μm to 60 μm of the adhesive layer 501B of the grinding tape 501.

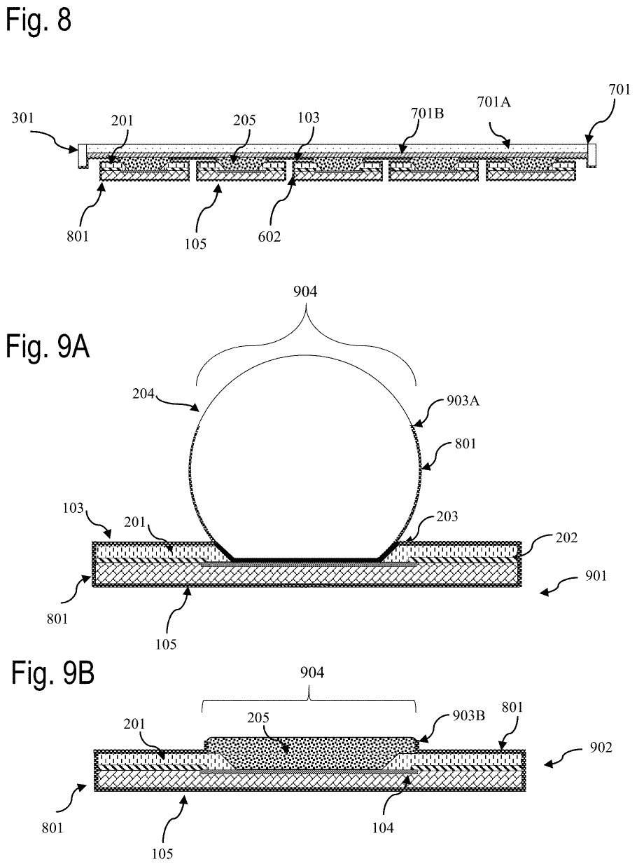

After the later electrical contact areas are covered by the tape 701, a passivation layer 801 is deposited by ALD as illustrated in FIG. 8 (step d). By the ALD process all six sides of each die, the frontside 103, the backside 105 and the four lateral sides 602, are passivated at the same time.

In contrast to other methods, in the described method no expansion of the tapes 501 or 701 in order to enlarge the distance between the lateral sides 602 of the dies 101 is required. Here, such a step is superfluous since passivation by an ALD process allows the deposition of single passivation layers in nanometer scale. By repeatedly applying such mono-layers, layer thicknessness up to μm scale can be achieved. Therefore, neither the small distances between facing lateral sides 602, which are equal to the width of the dicing streets 302, nor the small gaps between the frontside 103 of the die and the tape 701 do hinder uniform deposition of passivation.

Furthermore, an ALD process has the main advantages of being capable of depositing layers in a low temperature regime with a high uniformity and quality and being capable of covering high aspect ratio topographies with minimum variation of less than 1 nm. Only the ALD process allows a thin-film deposition of passivation layers based on metal nitrides or metal oxides like alumina since the required temperature in a CVD process would be higher than the decomposition temperature of most polymers. In contrast to CVD, ALD can be performed at low temperatures, i.e. around room temperature. CVD for passivation processes is performed at elevated temperatures above 150° C.

When the deposition of the passivation layer 801 is completed, the passivation tape 701 is detached from the dies 101 (step e). The releasing can be forced by heating, UV exposure or a different method depending on the adhesive's properties. A usual fatigue strength of the first adhesive layer 701B of the passivation tape 701 is about 6 to 8 N/mm². When releasing the tape 701 from the dies 101, the passivation layer 801 that is also deposited to the bottom surface of the tape 701 delaminates at the upper edge between the protrusion and the tape 701, since the edge is a weak point of said layer.

For example, the passivation layer 801 delaminates at the upper edge of a thick film metallization 205 and the tape 701 or at the edge between a solder bump 204 and the tape 701. The exact borderline of the passivation layer 801 can be defined by the thickness of the adhesive layer 701B of the tape 701. A thick adhesive layer 701B covers a large area of the solder bump 204 or of the thick film metallization 205. Thus, on a large area of the solder bump 204 or of the thick film metallization 205 no passivation layer can be deposited. The borderline runs close to the surface of the die.

On the other hand, a thin adhesive layer 701B covers a comparatively smaller portion of the solder bump 204 or of the thick film metallization 205. Thus, the passivation layer 801 can be deposited on a larger portion of the solder bump 204 or of the thick film metallization 205. In such a way, the size of an electric contact area not covered by the passivation layer 801 can be defined. Hence, this size can be defined exactly.

The resulting dies 901 and 902 with passivation layer 801 are shown in figure 9A and 9B, wherein the protrusion is a solder bump 204 in FIG. 9A (die 901) or a thick film metallization 205 in FIG. 9B (die 902). The passivation layer 801 is laminated on all sides of the die 101 and ends at the upper edges 903A or 903B of the protrusions 204 or 205. The area not covered by the passivation layer 801 defines the electrical contact area 904.

The passivation layer 801 may consist of a dielectric material such as alumina (Al₂O₃ ), which allows high electrical insulation. Other possible materials are AlN or a mixture of Al₂O₃ and TiO₂. The exact composition of the passivation layer material depends on external influences, the required material qualities such as electrical resistance, thermal conductivity and temperature resistance and on material costs.

The passivation layer 801 protects the semiconductor die 101 against external influences such as moisture, chemical contamination or mechanical damages in the following process steps.

In one embodiment not shown in the figures the semiconductor die may be used for forming a micro-electro-mechanical system (MEMS) device for a variety of applications such as sensing, protection, power electronics, etc.

In another embodiment not shown in the figures the die may comprise a mineral material. The mineral material may comprise a ceramic. The electric device of the die may be embodied as capacitor, varistor or thermistor.

In another embodiment not shown in the figures the wafer may comprise a mineral material. The wafer may be divisible in singulated dies. The mineral material may comprise a ceramic. The electric devices of the dies may be embodied as capacitor, varistor or thermistor.

Although the invention has been illustrated and described in detail by means of the preferred embodiment examples, the present invention is not restricted by the disclosed examples and other variations may be derived by the skilled person without exceeding the scope of protection of the invention.

1.-21. (canceled)

22. A method for manufacturing and passivating a die, the method comprising:
providing the die comprising an active frontside having a protrusion, the protrusion configured for electrically contacting the die;
covering a portion of the protrusion by a passivation tape before applying a passivation layer;
applying the passivation layer on all sides of the die including the frontside and its protrusion in one single process, except on the portion covered by the passivation tape; and
detaching the passivation tape from the covered portion of the protrusion after applying the passivation layer to expose the portion of the protrusion which forms an electrical contact area.

23. The method of claim 22, wherein the passivation tape comprises a first base layer having a first adhesive layer thereon.

24. The method of claim 22, wherein the die comprises a semiconductor material.

25. The method of claim 22, wherein the passivation layer is deposited by atomic layer deposition.

26. A wafer level packaging method comprising:
providing a wafer comprising an active frontside with several protrusions, which are configured for electrically contacting a die, and a passive backside;
singulating the wafer into single dies, each with at least one protrusion;
covering a portion of each protrusion by a passivation tape before applying a passivation layer;
applying the passivation layer on all sides, including the frontside, the backside and all lateral sides of the singulated dies in one single process, except on the portions covered by the passivation tape; and
detaching the passivation tape from the covered portions of the protrusions after applying the passivation layer to expose the portions of the protrusions which form electrical contact areas.

27. The method of claim 26, wherein the passivation tape comprises a first base layer having a first adhesive layer thereon.

28. The method of claim 26, wherein the wafer comprises a semiconductor material.

29. The method of claim 26, wherein the passivation layer is deposited by atomic layer deposition. 3o. (New) The method of claim 26 wherein singulating comprises:
partially dicing the wafer into the dies, each with at least one protrusion, from the frontside;
laminating a grinding tape to the frontside of the wafer, the grinding tape comprising a second base layer having a second adhesive layer thereon;
singulating the dies by grinding the wafer from the backside; and
releasing the grinding tape from the singulated dies.

31. The method of claim 3o, wherein the second adhesive layer on the grinding tape is thicker than a first adhesive layer on the passivation tape.

32. The method of claim 3o, wherein a distance between two adjacent dies while applying the passivation layer is kept equal to a width of a dicing street formed by partially dicing.

33. The method of claim 30, further comprising applying a protective layer on the frontside of the wafer before partially dicing.

34. The method of claim 30, wherein the backside is covered with a dicing tape while partially dicing the wafer into the dies from the frontside.

35. The method of claim 34, further comprising detaching tapes by physical methods comprising at least one of UV-exposure or heating.

36. The method of claim 26, wherein the protrusion is a solder bump on the die, and wherein the solder bump is partially covered by the passivation layer while applying the passivation layer.

37. The method of claim 26, wherein the protrusion is a thick film metallization on the die, and wherein the thick film metallization is partially covered by the passivation layer while applying the passivation layer.

38. A die comprising:
a passivation layer covering all sides and edges of the die except an electrical contact area on a protrusion,
wherein the passivation layer is uniform, continuous and homogeneous on every side.

39. The die of claim 38, wherein the die comprises a MEMS arranged on a semiconductor die.

40. The die of claim 38, wherein a frontside of the die comprises a protective layer and the passivation layer all around the die, wherein the passivation layer is arranged on the protective layer, and wherein materials of the two layers are different from each other.

41. The die of claim 38, wherein the passivation layer is electrically insulating.

42. The die of claim 38, wherein the passivation layer comprises one or more of Al₂O₃, AlN or TiO₂.
